(19) United States
(12) Patent Application Publication
(10) Pub. No.: US 2012/0181551 A1
(43) Pub. Date: Jul. 19, 2012

(54) SILICON CARBIDE SEMICONDUCTOR DEVICE

(75) Inventors: Shinichiro Miyahara, Nisshin-city (JP); Hidefumi Takaya, Toyota-city (JP); Masahiro Sugimoto, Toyota-city (JP); Yukihiko Watanabe, Nagoya-city (JP); Narumasa Soejima, Seto-city (JP); Tsuyoshi Ishikawa, Nisshin-city (JP)

(73) Assignees: TOYOTA JIDOSHA KABUSHIKI KAISHA, Toyota-city (JP); DENSO CORPORATION, Kariya-city (JP)

(21) Appl. No.: 13/348,781

(22) Filed: Jan. 12, 2012

(30) Foreign Application Priority Data
Jan. 14, 2011 (JP) 2011-5970

(51) Int. Cl. H01L 29/24

(52) U.S. Cl. 257/77; 257/E29.104

(57) ABSTRACT

A silicon carbide semiconductor device includes a silicon carbide semiconductor substrate and a trench. The silicon carbide semiconductor substrate has an offset angle with respect to a (0001) plane or a (000-1) plane and has an offset direction in a <11-20> direction. The trench is provided from a surface of the silicon carbide semiconductor substrate. The trench extends in a direction whose interior angle with respect to the offset direction is 30 degrees or −30 degrees.

### CROSS REFERENCE TO RELATED APPLICATIONS

The present application is based on and claims priority to Japanese Patent Application No. 2011-5970 filed on Jan. 14, 2011, the disclosure of which is incorporated herein by reference.

### TECHNICAL FIELD

The present invention relates to a silicon carbide (hereafter, referred to as SiC) semiconductor device including a trench.

### BACKGROUND

Conventionally, a SiC semiconductor device includes a semiconductor element, such as a metal-oxide semiconductor field-effect transistor (MOSFET) and a junction field transistor (J-FET), formed in a SiC semiconductor substrate, and the semiconductor element has a trench gate structure. For example, JP-A-2006-156962 (corresponding to US 2006/0097268 A1) discloses a SiC semiconductor device that includes an N⁺-type substrate having an offset angle with respect to a (0001) plane and having an offset direction in a <11-20> direction. On the N⁺-type substrate, an N⁻-type drift layer, a P⁺-type base region, and an N⁺-type source region are epitaxially grown in this order to form a SiC semiconductor substrate, and a trench is provided in the SiC semiconductor substrate.

Specifically, the trench is provided from a main surface of the SiC semiconductor substrate to the N⁻-type drift layer through the N⁺-type source region and the P⁺-type base region. On an inner wall of the trench, a channel layer is formed. In addition, an oxide layer is formed to cover the channel layer and a part of the N⁺-type source region. On a portion of a surface of the oxide layer located in the trench, a gate electrode made of polysilicon or metal is formed so as to fill the trench.

At a portion of the SiC semiconductor substrate different from a portion where the trench is provided, a contact trench is provided. The contact trench penetrates the N⁺-type source region to the P⁺-type base region. In the contact trench, a source electrode electrically coupled with the P⁺-type base region and the N⁺-type source region is formed. On a rear surface of the SiC semiconductor substrate, a drain electrode is formed.

The N⁻-type drift layer, the P⁺-type base region, and the N⁺-type source region inherit a surface state of the SiC substrate. Thus, the SiC semiconductor substrate as a whole has an offset angle with respect to the (0001) plane and has an offset direction in the <11-20> direction.

When a predetermined gate voltage is applied to the gate electrode of the SIC semiconductor device, a channel region is formed in the channel layer, and electric current flows between the source electrode and the drain electrode.

Because the channel layer is formed along a sidewall of the trench, a plane direction of the channel region is same as a plane direction of the trench. From the viewpoint of a mobility and a threshold voltage Vt of the gate voltage, it is preferable that the plane direction of the channel region is a {11-20} plane. Thus, in the above-described semiconductor device, the trench extends, for example, in a <-1100> direction so that the sidewall is provided along the {11-20} plane. That is, the trench extends in a direction whose interior angle with respect to the offset direction is 90 degrees.

However, in the above-described SiC semiconductor device, the sidewall of the trench is generally not perpendicular to the surface of the SiC semiconductor substrate, and the trench has a taper shape in which an open end portion has a larger area than a bottom. Since the SiC semiconductor substrate has the offset angle, opposite sidewalls of the trench that extend in parallel with the extending direction of the trench have different plane direction. In other words, an angle between a sidewall of the trench located on an upstream side in the offset direction and the (0001) plane is different from an angle between a sidewall of the trench located on a downstream side in the offset direction and the (0001) plane.

In a SiC semiconductor substrate shown in FIG. 8, a trench extends in a direction whose interior angle with respect to the offset direction is 90 degrees.

The SiC semiconductor substrate shown in FIG. 8 has an offset angle of 4 degrees with respect to the (0001) plane and has an offset direction in the <11-20> direction.

As shown in FIG. 8, when an interior angle (taper angle) between sidewalls J2a, J2b of a trench J2 and a surface of a SiC semiconductor substrate J1 is 87 degrees, since the offset angle is 4 degrees, an angle between the sidewall J2a of the trench J2 located on an upstream side in the offset direction (hereafter, referred to as the upstream sidewall J2a) and the (0001) plane is 91 degrees. On the other hand, an angle between the sidewall J2b of the trench J2 located on a downstream side in the offset direction (hereafter, referred to as the downstream sidewall J2b) and the (0001) plane is 83 degrees. In other words, the angle between the upstream sidewall J2a and the (0001) plane and the angle between the downstream sidewall J2b and the (0001) plane are different from each other.

Because, a plane direction of a channel region formed along the upstream sidewall J2a and a plane direction of a channel region formed along the downstream sidewall J2b are different from each other by 8 degrees, an unbalance of electric current occurs, and the SiC semiconductor device may be damaged.

Although the above-described semiconductor device includes the trench provided in the SiC semiconductor substrate having the offset angle with respect to the (0001) plane, similar issues occurs also in a SiC semiconductor device that includes a trench provided in a SiC semiconductor substrate having an offset angle with respect to the (000-1) plane.

### SUMMARY

In view of the foregoing problems, it is an object of the present invention to provide a silicon carbide semiconductor device in which a difference in plane direction between opposite sidewalls of a trench extending in an extending direction of the trench can be restricted.

A silicon carbide semiconductor device according to an aspect of the present invention includes a silicon carbide semiconductor substrate and a trench. The silicon carbide semiconductor substrate has an offset angle with respect to a (0001) plane or a (000-1) plane and has an offset direction in a <11-20> direction. The trench is provided from a surface of the silicon carbide semiconductor substrate. The trench extends in a direction whose interior angle with respect to the offset direction is 30 degrees or −30 degrees.

In the above-described silicon carbide semiconductor device, a difference in plane direction between opposite sidewalls of the trench extending in an extending direction of the trench can be restricted, and each of the sidewalls can be formed along an approximately {11-20} plane.

### BRIEF DESCRIPTION OF THE DRAWINGS

Additional objects and advantages of the present invention will be more readily apparent from the following detailed description when taken together with the accompanying drawings. In the drawings:

FIG. 1 is a diagram showing a SiC semiconductor device according to a first embodiment of the present disclosure;

FIG. 2 is a diagram showing a SiC semiconductor device according to a second embodiment of the present disclosure;

FIG. 3 is a diagram showing a SiC semiconductor device according to a third embodiment of the present disclosure;

FIG. 4 is a diagram showing a SiC semiconductor device according to a fourth embodiment of the present disclosure;

FIG. 5 is a diagram showing a SiC semiconductor device according to a fifth embodiment of the present disclosure;

FIG. 6A is a diagram showing a semiconductor substrate in which a trench extends in a direction whose interior angle with respect to an offset direction is 90 degrees, and FIG. 6B is a cross-sectional view of the semiconductor substrate taken along line VIB-VIB in FIG. 6A;

FIG. 7A is a diagram showing a semiconductor substrate in which a trench extends in a direction whose interior angle with respect to an offset direction is 30 degrees, and FIG. 7B is a cross-sectional view of the semiconductor substrate taken along line VIIB-VIIB in FIG. 7B; and

FIG. 8 is a cross-sectional view of a semiconductor substrate according to a related art in which a trench extends in a direction whose interior angle with respect to an offset direction is 90 degrees.

### DETAILED DESCRIPTION

Before describing embodiments of the present disclosure, a study performed by the inventors will be described. According to the study, when a trench extends in a direction whose interior angle with respect to the offset angle is 30 degrees or −30 degrees, the sidewalls of the trench can be formed along an approximately {11-20} plane and the opposite sidewalls can have substantially the same plane direction.

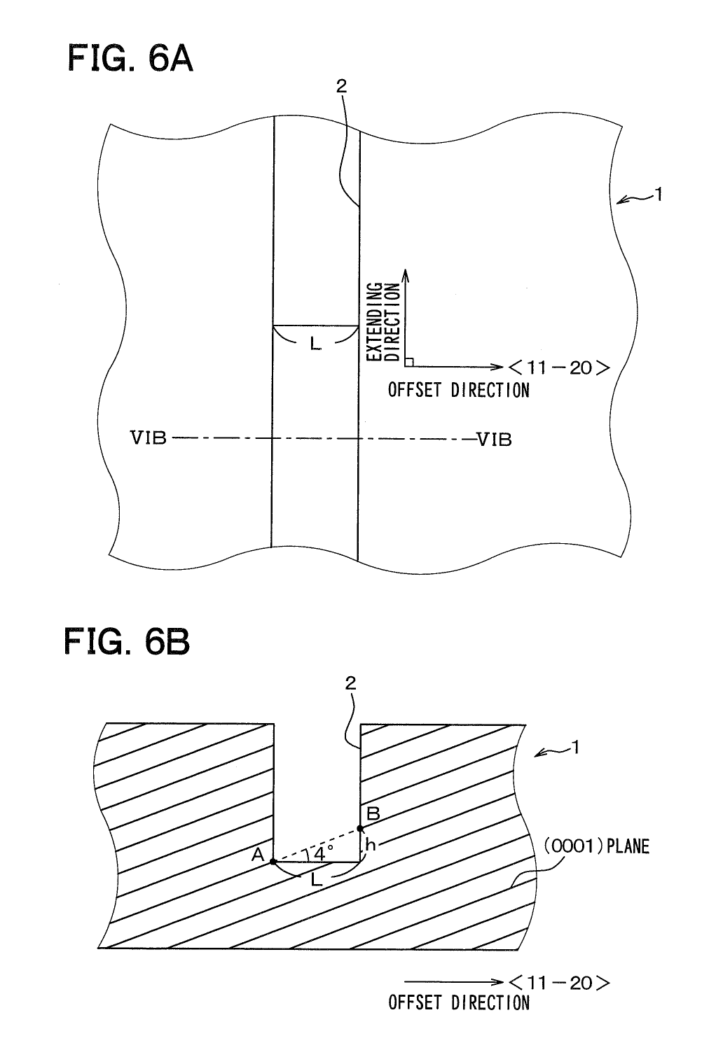

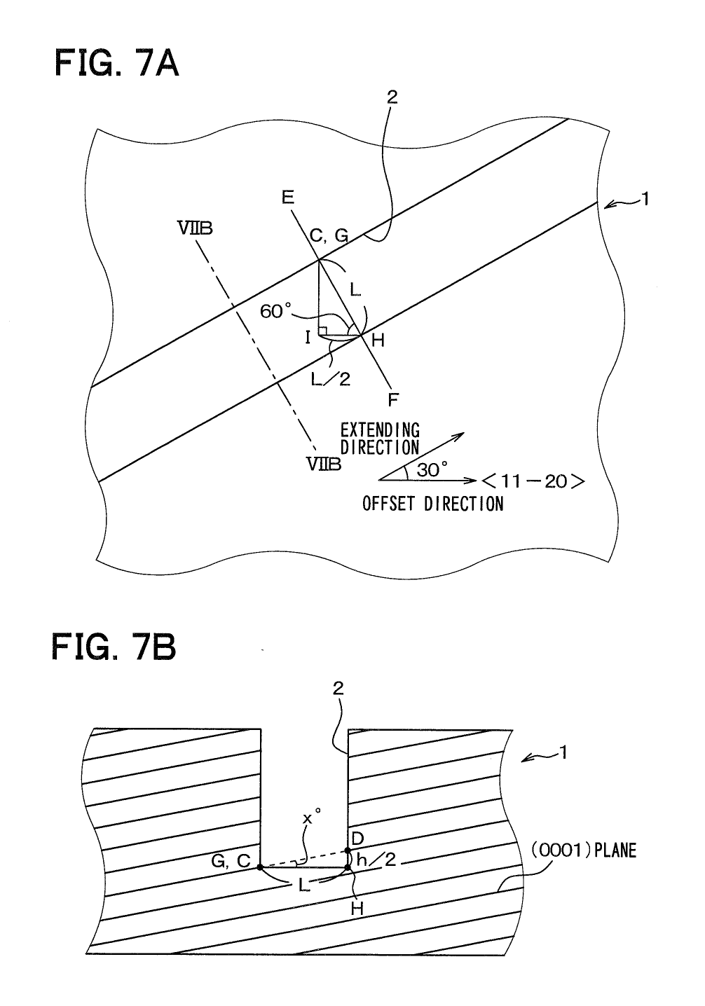

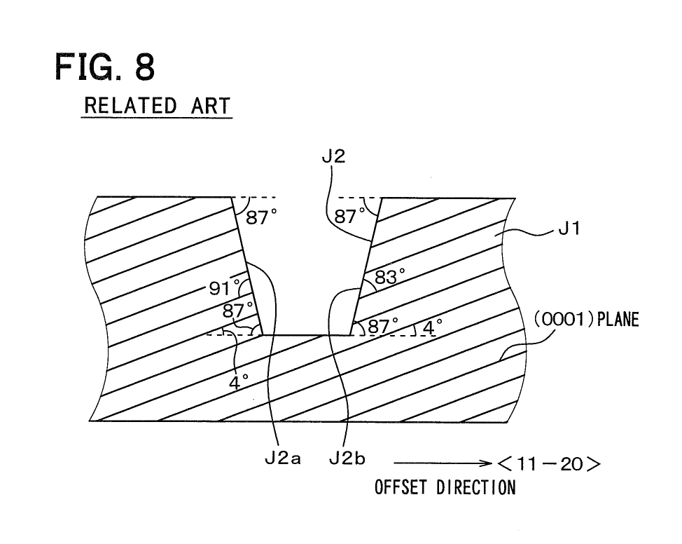

In a SiC semiconductor substrate 1 shown in FIG. 6A and FIG. 6B, a trench 2 extends in a direction whose interior angle with respect to an offset direction is 90 degrees. In a SiC semiconductor substrate 1 shown in FIG. 7A and FIG. 7B, a trench 2 extends in a direction whose interior angle with respect to an offset direction is 30 degrees. In each of FIG. 6B and FIG. 7B, the trench 2 is drawn as being perpendicular to a surface of the SiC semiconductor substrate 1 for the sake of convenience. Each of the SiC semiconductor substrate 1 has an offset angle of 4 degrees with respect to the (0001) plane and has an offset direction in the <11-20> direction.

As shown in FIG. 6A and 6B, in a case where the trench 2 is formed in the direction whose interior angle with respect to the offset direction is 90 degrees, a trench width in a direction perpendicular to the extending direction is represented by L, a point of the (0001) plane that intersects with an upstream sidewall of the trench 2 is represented by a point A, a point of the (0001) plane that intersects with a downstream sidewall of the trench 2 is represented by a point B, and a difference between the point A and the point B in a thickness direction of the SiC semiconductor substrate 1 is represented by h, tan 4 degrees=h/L.

In a case where the trench 2, which has a width L, extends in the direction whose interior angle with respect to the offset direction is 30 degrees as shown in FIG. 7A and FIG. 7B, a point of the (0001) plane at which a straight line perpendicular to an extending direction of the trench 2 intersects with an upstream sidewall of the trench 2 is represented by a point C, a point of the (0001) plane at which a straight line perpendicular to the extending direction intersects with a downstream sidewall of the trench 2 is represented by a point D, a difference between the point C and the point D in a thickness direction of the SiC semiconductor substrate 1 can be expressed as follows.

As shown in FIG. 7A, a segment that extends perpendicularly to the extending direction of the trench 2 and is parallel to the surface of the SiC semiconductor substrate 1 is represented by a segment EF, an intersection point of the segment EF with the upstream sidewall of the trench 2 is represented by a point G, an intersection point of the segment EF with the downstream sidewall of the trench 2 is represented by a point H, and an intersection point of a segment that passes through the point H and is parallel to the offset direction and a segment that passes through the point G and is perpendicular to the segment passing through the point H is represented by I, a triangle defined by the points G, H, I is a right triangle in which an angle H is 60 degrees and an angle I is 90 degrees. A segment GH has a length equal to the width L of the trench 2. Thus, a length of a segment HI is 2/L.

Thus, as shown in FIG. 7A and FIG. 7B, since the point D and the point H are located at different positions in the thickness direction, a distance between the point C and the point C in a direction parallel to the offset direction is L/2. When a distance between the point A and the point B in the offset direction is L, a distance between the point A and the point B in the thickness direction is h. Thus, a difference between the point C and the point D in the thickness direction is h/2.

Since tan×degrees=h/2L and tan 4 degrees=h/L, ×degrees=2 degrees. Thus, a case where the trench 2 extends in the direction whose interior angle with respect to the offset direction is 30 degrees is similar to a case where the trench 2 is provided in the SiC semiconductor substrate having an offset angle of 2 degrees so that the trench extends in a direction perpendicular to the offset direction. For example, when an interior angle (taper angle) between the surface of the SiC semiconductor substrate 1 and the sidewalls of the trench 2 is 87 degrees, the interior angle between the upstream sidewall of the trench 2 and the (0001) plane is 89 degrees, and the interior angle between the downstream sidewall of the trench 2 and the (0001) plane is 85 degrees. Therefore, the difference in plane direction between the opposite sidewalls extending in the extending direction of the trench 2 can be 4 degrees, and the difference in plane direction can be restricted.

Although a case where a trench is provided in a SiC semiconductor substrate having an offset angle with respect to the (0001) plane is described above, similar advantage can be obtained also in a case where a trench is provided in a SiC semiconductor substrate having an offset angle with respect to the (000-1) plane.

### First Embodiment

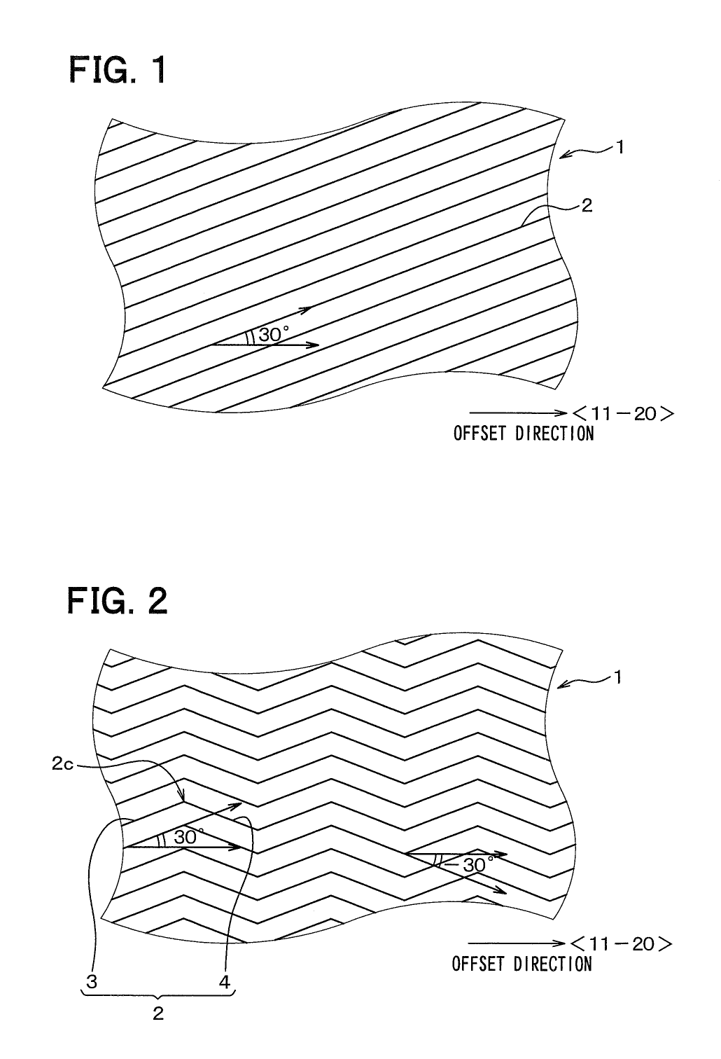

A silicon carbide semiconductor device according to a first embodiment of the present disclosure will be described with reference to FIG. 1.

In the present embodiment, a SiC semiconductor substrate 1 has an offset angle of 4 degrees with respect to the (0001) plane and has an offset angle in the <11-20> direction. In the SiC semiconductor substrate 1, a trench 2 is provided. The trench 2 extends in a direction whose interior angle with respect to the offset direction is 30 degrees. Hereafter, the direction in which the trench 2 extends is referred to as an extending direction.

An interior angle between a straight line extending in parallel with the offset direction and a straight line extending in parallel with the extending direction of the trench 2 is 30 degrees. Opposite sidewalls of the trench 2 are provided approximately along a {11-20} plane. The trench 2 is formed, for example, by anisotropic etching, and has a taper shape in which an open end portion has a larger area than a bottom.

The direction whose interior angle with respect to the offset direction is 30 degrees is a direction in a case where the extending direction is located in a counterclockwise direction with respect to the offset direction. A direction whose interior angle with respect to the offset direction is −30 degrees is a direction in a case where the extending direction is located in a clockwise direction with respect to the offset direction. In other words, the direction whose interior angle with respect to the offset direction is 30 degrees is a direction whose interior angle with respect to the offset direction −150 degrees, and the direction whose interior angle with respect to the offset direction is −30 degrees is a direction whose interior angle with respect to the offset direction 150 degrees. In the present application, the direction whose interior angle with respect to the offset direction is 30 degrees or −30 degrees may include margins such as production errors. For example, the direction whose interior angle with respect to the offset direction is 30 degrees or −30 degrees may include a direction whose interior angle with respect to the offset direction is 30±5 degrees or −30±5 degrees.

Using the SiC semiconductor substrate 1, the SiC semiconductor device having the following trench structure is formed as an example. The SiC semiconductor substrate 1 includes an N⁺-type SiC substrate having an offset angle with respect to the (0001) plane and having an offset direction in the <11-20> plane. On the Nr-type SiC substrate, an N⁻-type drift layer, a P⁺-type base region, and an N⁺-type source region are epitaxially grown in this order.

The trench 2 is provided from a main surface of the SiC semiconductor substrate 1 to the N⁻-type drift layer through the N⁺-type source region and the P⁺-type base region. On an inner wall of the trench 2, an N⁻-type channel layer is formed. In addition, an oxide layer is formed to cover the N⁻-type channel layer and a part of the B⁺-type source region. On a portion of a surface of the oxide layer located in the trench 2, a gate electrode made of polysilicon or metal is formed so as to fill the trench.

At a portion of the SiC semiconductor substrate 1 different from a portion where the trench 2 is provided, a contact trench is provided. The contact trench penetrates the N⁺-type source region to the P⁺-type base region. In the contact trench, a source electrode electrically coupled with the P⁺-type base region and the N⁺-type source region is formed. On a rear surface of the SiC semiconductor substrate 1, a drain electrode is formed.

The N⁻-type drift layer, the P⁺-type base region, and the N⁺-type source region inherit a surface state of the N⁺-type SiC substrate. Thus, the SiC semiconductor substrate 1 as a whole has an offset angle with respect to the (0001) plane and having an offset direction in the <11-20> direction.

As described above, in the SiC semiconductor according to the present embodiment, the trench 2 extends in the direction whose interior angle with respect to the offset direction is 30 degrees. Thus, the difference in plane direction between the opposite sidewalls of the trench 2, which extend in parallel with the extending direction of the trench 2, can be restricted. Thus, generation of unbalance of electric current can be restricted, and the SiC semiconductor device is less likely to be damaged.

### Second Embodiment

A SiC semiconductor device according to a second embodiment of the present disclosure will be described with reference to FIG. 2.

A trench 2 according to the present embodiment includes a first trench 3 and a second trench 4, which are alternately formed. The first trench 3 extends in a direction whose interior angle with respect to the offset direction is 30 degrees. The second trench 4 extends in a direction whose interior angle with respect to the offset direction is −30 degrees. The first trench 3 and the second trench 4 are connected with each other. In other words, the trench 3 has a wavy shape having an edge portion 2c.

In the SiC semiconductor device, electric current is less likely to concentrate in a channel region that is formed along one of sidewalls of the trench 2.

In the SiC semiconductor device according to the first embodiment, although the difference in plane direction between the opposite sidewalls can be restricted, the plane directions do not completely correspond to each other. Thus, in the SiC semiconductor device according to the first embodiment, the plane direction of the channel region formed along the upstream sidewall of the trench 2 is close to the {11-20} plane compared with the plane direction of the channel region formed along the downstream sidewall of the trench 2, and a current density becomes high.

In contrast, in the present embodiment, because the first trench 3 and the second trench 4 are alternately formed, the sidewall close to the {11-20} plane is alternately formed. Thus, electric current is less likely to concentrate in the channel region that is formed along one of the sidewalls of the trench 2.

### Third Embodiment

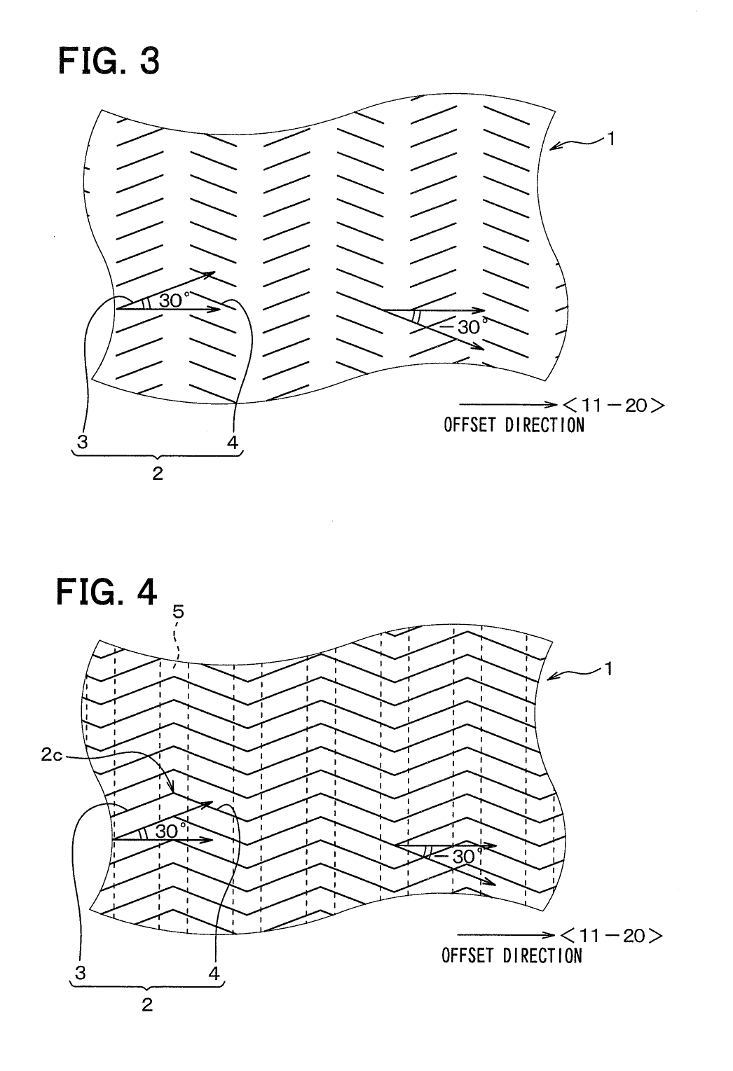

A SiC semiconductor device according to a third embodiment of the present disclosure will be described with reference to FIG. 3.

A trench 2 according to the present embodiment includes the first trench 3 and the second trench 4 located at a distance from each other. Thus, the trench 2 does not include an edge portion 2c. Because the trench 2 does not include the edge portion 2c, electric current is less likely to concentrate in a portion where the first trench 3 and the second trench 4 are connected compared with the second embodiment.

### Fourth Embodiment

A SiC semiconductor device according to a fourth embodiment of the present disclosure will be described with reference to FIG. 4. The SiC semiconductor device according to the present embodiment is similar to the SiC semiconductor device according to the second embodiment, and further includes an electric field relaxation layer 5 in the SiC semiconductor substrate 1.

As shown in FIG. 4, the electric field relaxation layer 5 is formed at a portion of the SiC semiconductor substrate 1 located under the edge portion 2c where the first trench 3 and the second trench 4 are connected. Specifically, at the portion under the edge portion 2c, the electric field relaxation layer 5 extends in a direction perpendicular to the offset direction. When the SiC substrate has N-type conductivity, the electric filed relaxation layer 5 has P-type conductivity.

In the SiC semiconductor device according to the present embodiment, because the electric field relaxation layer 5 is formed at the portion of the SiC semiconductor substrate 1 located under the edge portion 2c of the trench 2, electric current is less likely to concentrate at the edge portion 2c where the first trench 3 and the second trench 4 are connected.

### Fifth Embodiment

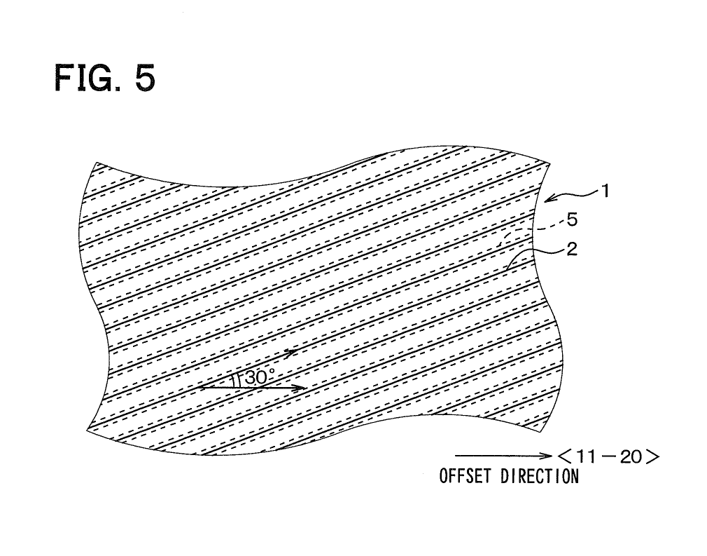

A SIC semiconductor device according to a fifth embodiment of the present disclosure will be described with reference to FIG. 5. The SiC semiconductor device according to the present embodiment is similar to the SiC semiconductor device according to the first embodiment, and further includes an electric field relaxation layer 5 in the SiC semiconductor substrate 1.

As shown in FIG. 5, in the present embodiment, the electric field relaxation layer 5 is disposed at a portion of the SiC semiconductor substrate 1 under the trench 2. Specifically, the electric field relaxation layer 5 extends in a direction parallel to the extending direction of the trench 2. When the SiC substrate has N-type conductivity, the electric field relaxation layer 5 has P-type conductivity.

In the SiC semiconductor device according to the present embodiment, because the electric field relaxation layer 5 is disposed under the trench 2, electric field is less likely to concentrate under the trench 2 compared with the SiC semiconductor device according to the first embodiment.

### Other Embodiments

Although the present invention has been fully described in connection with the preferred embodiments thereof with reference to the accompanying drawings, it is to be noted that various changes and modifications will become apparent to those skilled in the art.

For example, although each of the SiC semiconductor devices according to the above-described embodiments includes the SiC semiconductor substrate 1 having the offset angle with respect to the (0001) plane, the SiC semiconductor substrate having an offset angle with respect to the (000-1) plane may also be used. Also in this case, similar advantages can be obtained.

Although each of the SiC semiconductor devices according to the above-described embodiments includes the MOSFET having the trench structure as an example, the above-described disclosure can also be applied to a J-FET having a trench structure.

The trench 2 in the SiC semiconductor device according to the first embodiment extends in the direction whose interior angle with respect to the offset direction is 30 degrees as an example. Alternatively, the trench 2 may extend in the direction whose interior angle with respect to the offset direction is −30 degrees.

In the SiC semiconductor device according to the fifth embodiment, the electric field relaxation layer 5 extends in the direction parallel to the extending direction of the trench 2. Alternatively, the electric field relaxation layer 5 may have a striped shape extending in a direction perpendicular to the extending direction of the trench 2.

What is claimed is:

1. A silicon carbide semiconductor device comprising:
a silicon carbide semiconductor substrate having an offset angle with respect to a (0001) plane or a (000-1) plane and having an offset direction in a <11-20> direction; and
a trench provided from a surface of the silicon carbide semiconductor substrate, the trench extending in a direction whose interior angle with respect to the offset direction is 30 degrees or −30 degrees.

2. The silicon carbide semiconductor device according to claim 1, wherein
the trench includes a first trench and a second trench that are alternately arranged,
the first trench extends in the direction whose interior angle with respect to the offset direction is 30 degrees, and
the second trench extends in the direction whose interior angle with respect to the offset direction is −30 degrees.

3. The silicon carbide semiconductor device according to claim 2, wherein the first trench and the second trench are located at a distance from each other.

4. The silicon carbide semiconductor device according to claim 2, wherein
the trench has a wavy shape in which the first trench and the second trench are connected with each other,
the trench has an edge portion where the first trench and the second trench are connected, and
the silicon carbide semiconductor substrate includes an electric field relaxation layer located under the edge portion.

5. The silicon carbide semiconductor device according to claim 1, wherein
the silicon carbide semiconductor substrate includes an electric field relaxation layer located under the trench.

6. The silicon carbide semiconductor device according to claim 5, wherein
the electric field relaxation layer extends in parallel with an extending direction of the trench.

7. The silicon carbide semiconductor device according to claim 5, wherein
the electric field relaxation layer has a striped shape extending in a direction perpendicular to an extending direction of the trench.
